(19) United States
(12) Patent Application Publication
(10) Pub. No.: US 2013/0222159 A1
(43) Pub. Date: Aug. 29, 2013

(54) ENTROPY METHOD OF BINARY-TERNARY LOSSLESS DATA CODING

(71) Applicants: Igor Valeryevich Nesiolovskiy, Podolsk (RU); Artem Igorevich Nesiolovskiy, Podolsk (RU)

(72) Inventors: Igor Valeryevich Nesiolovskiy, Podolsk (RU); Artem Igorevich Nesiolovskiy, Podolsk (RU)

(21) Appl. No.: 13/405,936

(22) Filed: Feb. 27, 2012

(51) Int. Cl. H03M 7/34

(52) U.S. Cl. 341/51

(57) ABSTRACT

Subject of this invention is a new lossless data compression method. It is characterized by the simplicity of implementation, high speed and good compression efficiency. The method is based on a unique scheme of binary-ternary prefix-free encoding of characters or bit-series of the original data. This scheme does not require the transmission of the code tables and frequencies of character appearances from encoder to decoder; allows for the linear presentation of the code lists; permits the usage of computable index of the prefix codes in a linear list for decoding; makes it possible to estimate the compression ratio prior to encoding; makes the usage of multiplication and division operations, as well as operations with the floating point unnecessary; proves to be effective for static as well as adaptive coding; applicable to character sets of any size; allows for repeated compression to improve the ratio.

### CROSS REFERENCE

### OTHER PUBLICATIONS

I. Nesiolovskiy, A. Nesiolovskiy, BIN@ERN: Binary-Ternary Compressing Data Coding, 26 Jan. 2012, http://arxiv.org/abs/1201.5603

### FIELD OF INVENTION

Present invention relates to the field of universal compressive encoding of data, used in various computer systems, local as well as global networks (Intranet and Internet), telecommunication systems and devices, as well as any digital data processing equipment. The invention can be implemented within the software as well as hardware of above mentioned systems, networks and devices. Data encoded by the new method requires less space for storage and can be transmitted faster than the source data. The present invention also relates to the decoding of data which was encoded by the method of present invention.

### BACKGROUND OF INVENTION

In modern world, the volume of data that needs to be transmitted and stored is growing exponentially and often faster than the infrastructure used to process it, creating constant demand for data compression methods and technologies. Huffman coding, Shannon-Fano and Arithmetic coding are some of the few well known entropy encoding techniques, many variations of which are extensively used in lossless data compression solutions. The first two methods use prefix codes and characterized by higher speed, but in most cases somewhat inferior to the third method in the degree of compression. Huffman and Shannon-Fano coding are better suited for the two-pass (static) coding, while Arithmetic coding lends itself better to single-pass (adaptive) coding. All three methods are widely used because it is always a trade-off between the rate of compression and speed of the process, as well as the amount of memory, data storage and other resources involved in each encoding solution. That leaves a niche for a fast and effective method of entropy encoding, which can be implemented equally well with single-pass as well as with multi-pass encoding scheme.

### SUMMARY OF INVENTION

The present invention is a solution to an automated process of lossless data coding, which allows reducing information redundancy by encoding the data stream using unique sets of prefix codes to replace serial elements (bit-series or characters) of the original data. Therefore, the invention establishes: a method of identification of compressive prefix code sets, a method of generation of prefix codes in the set, a method of encoding and a method of decoding data using the above mentioned code sets.

### BRIEF DESCRIPTION OF DRAWINGS

This invention will be more apparent from the following description in conjunction with the appended drawings, in which

FIG. 1 illustrates a method of identification of the code sets of the present invention;

FIG. 2 illustrates a method of generation of prefix codes in the code set;

FIG. 3 illustrates a method of encoding source characters using prefix codes sets of the present invention;

FIG. 4 illustrates a method of decoding characters using prefix code sets of the present invention.

### DETAILED DESCRIPTION OF INVENTION

Invented entropy encoding method for lossless data compression will be described here with references to the drawings, which illustrate the expedient embodiment of the present invention.

A. The Scheme of the Code Set Identification

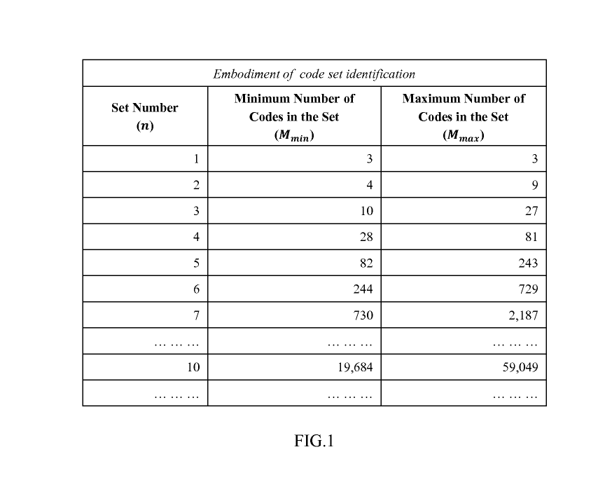

The invented method is based on a special scheme of entropy encoding of characters (or bit-strings) of the original and sequentially organized data using the sets of unique variable-length prefix codes. The key parameter, dependent on the original data, is the cardinal number m of the character set (or alphabet) used in the original data (total number of unique characters in the original data). Therefore, code sets are determined for different values of m as shown in FIG. 1 and identified by their number n as well as by the minimum Mₘᵢₙ and maximum Mₘₐₓ number of codes in each set. Theoretically, the number of these sets is unlimited. Number of a code set n is a consecutive natural number, starting with 1; minimum number of prefix codes in each set is defined by Mₘᵢₙ=3ⁿ⁻¹+1; while maximum number of prefix codes is defined by Mₘₐₓ=3ⁿ. It is assumed that original data sets with cardinal numbers m=1 and m=2 are obsolete for this method, as characters of such data can easily be encoded using simplest bit codes 0 and 1. Data with the cardinal number m=3 corresponds to the first set of codes n=1 which is distinct from the rest by concurrency of Mₘᵢₙ and Mₘₐₓ, while codes of this set are generated using the same scheme as the rest.

B. The Scheme Of Generation Of Codes In The Set

To generate prefix codes included in the set, identified in section A, it is necessary to perform the following steps 1-5:
1. Choose the number n of the code set to be generated;
2. Establish the base grid (character-length) of coding, where the number of positions (cells) is equal to the number of the code set n, chosen in step 1;
3. Build a set of base codes of the code set number n, using symbols zero (‘0’), one (‘1’) and two (‘2’), which:
   a. Includes all possible n-character combinations of symbols ‘0’, ‘1’, ‘2’ in the fully. filled (without gaps) base grid established in step 2;
   b. Sorted by the total number of zeros (‘0’) in the descending order;
   c. Divided into groups with equal number of zeros (‘0’) and additionally sorted in ascending lexicographic order within each group.
4. To build the final set of codes it is necessary to replace all ones (symbols ‘1’) with binary pairs ‘10’ and all twos (symbols ‘2’) with binary pairs ‘11’ in the base code set built in step 3;
5. Obtained in step 4 prefix codes are numbered using ascending consecutive natural numbers, starting with 1.

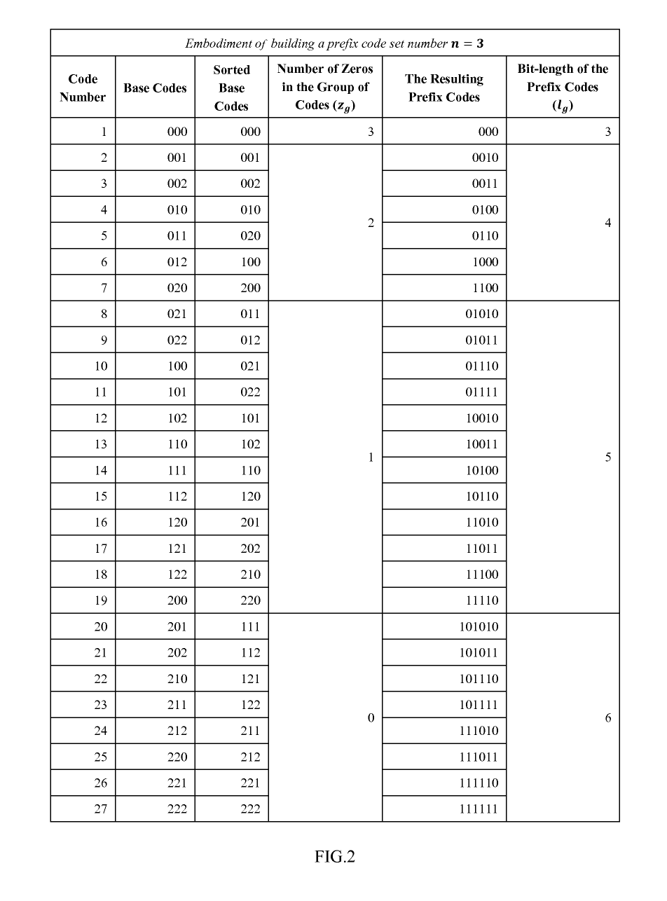

Thus, code set number n, identified in section A, is generated. Example and logic behind code set formation for the set number 3 (n=3) is shown in FIG. 2. The maximum number of codes in the set n is equal to Mₘₐₓ=3ⁿ, the number of code groups G with different number of base zeros is equal to G=n+1, the bit-length of prefix codes in each group g ∈ G is defined by l_{g}=2*n−z_{g}, where z_{g} is the number of base zeros in each base code within the group, the number of prefix codes in the group g ∈ G is defined by s_{g}=Cₙ^{z}^{_{g}}*2^{n-z}^{_{g}}, where Cₙ^{z}^{_{g}} is a disordered sample or number of z_{g}-combination from the set of n elements or

$${C}_{n}^{{z}_{g}} = \frac{n !}{{z}_{g} ! ( n - {z}_{g} ) !}$$

while Cₙⁿ=1.

C. Encoding Scheme Using Prefix Code Sets

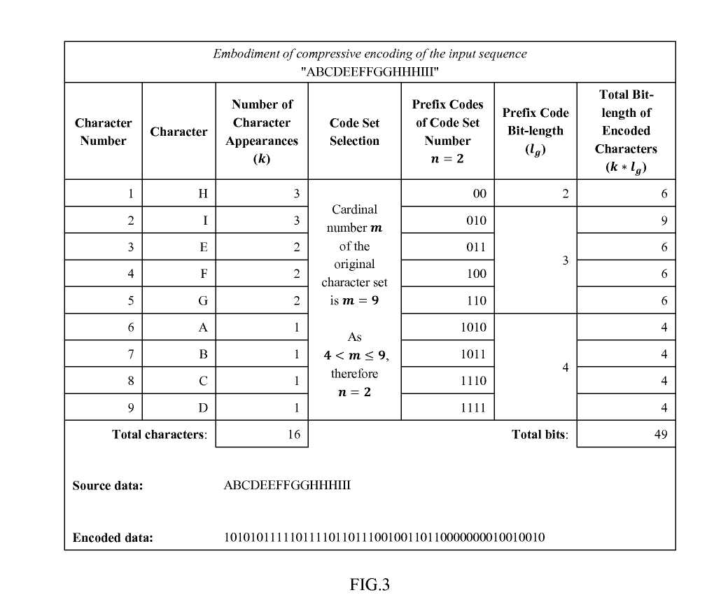

To encode data using particular set of prefix codes of the present invention, it is necessary to perform the following steps 1-7:
1. Establish the list of unique symbols (character set or alphabet) the original data is comprised of;
2. For each symbol established in step 1, determine the number of its appearances in the source data;
3. Sort the original character set (established in step 1) by the number of occurrences of individual symbols (determined in step 2) in descending order, then number the symbols using consecutive natural numbers, starting with 1;
4. Calculate the cardinal number m of the original character set (as a total number of unique symbols) the original data comprised of, to determine the number n of the corresponding prefix code set, identified in section A, where Mₘᵢₙ≦m≦Mₘₐₓ;
5. Generate m of the foremost prefix codes according to the method in section B, to be used from the code set number n, which is established in step 4 above;
6. Assign all resulting prefix codes to every symbol of the original character set, which was sorted and numbered in step 3 above, while matching the prefix code number with the corresponding number of a symbol from the sorted character set;
7. Sequentially, from the beginning through the end, replace all symbols in the original data with prefix codes assigned to each symbol in step 6 above. Thus, the encoding and compression of the source data is achieved. An example of encoding the sequence “ABCDEEFFGGHHHIII” is shown in FIG. 3.

D. Decoding Scheme Using Prefix Code Sets

To reconstruct the exact original data from the encoded data, it is necessary to perform the following steps 1-5:
1. Obtain from the encoder the identification number n of the prefix code set used for the encoding;
2. Obtain from the encoder the set of m unique symbols the source data comprised of, sorted in step 3 of section C, then number the sorted symbols using consecutive natural numbers, starting with 1;
3. Generate in of the foremost prefix codes of set number n obtained in step 1, in accordance with the method in section B;
4. To every prefix code, generated in step 3, assign a symbol of the original character set obtained in step 2, while matching the number of the code with the corresponding number of the symbol;

5. Sequentially, from the beginning through the end, substitute all prefix codes of the encoded data, generated by encoder in accordance with the method in section C, with the symbols of the original character set in accordance with step 4 above.

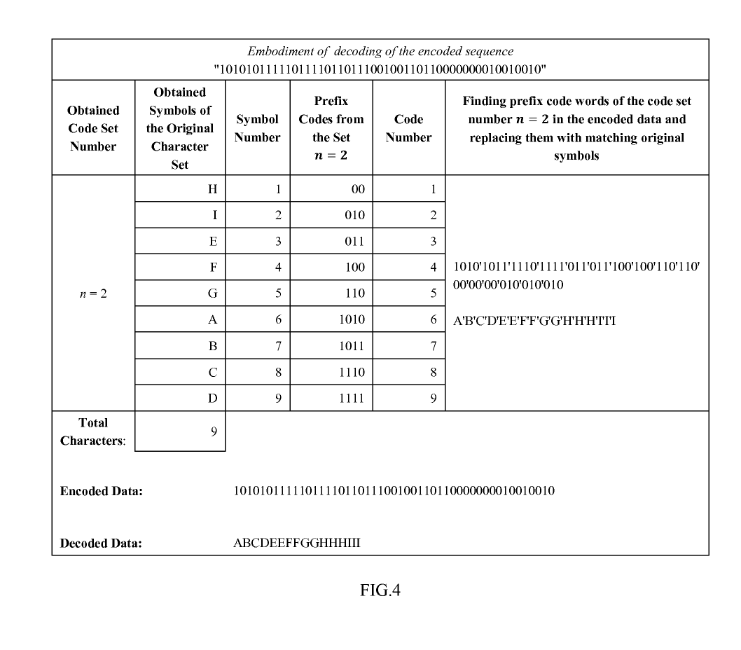

Therefore, the original data is restored. An example of decoding the sequence “1010101111101111011011100100110110000000010010010” from section C is shown in FIG. 4.

What is claimed is:

1. A method of identification of predetermined prefix code sets, comprising of:
a. Numbering the prefix code sets using consecutive natural numbers n, starting with 1;
b. Establishing the minimum number of codes in each code set Mₘᵢₙ=3ⁿ⁻¹+1, where n is the set number (Mₘᵢₙ=3 for the code set number n=1);
c. Establishing the maximum number of codes in each code set Mₘₐₓ=3ⁿ, where n is a set number.

2. A method of generation of binary-ternary prefix code sets, identified by the method of claim 1, comprising of:
a. Determining the number n of the prefix code set to be generated;
b. Establishing the base grid (character-length) of coding, where the number of positions (cells) is equal to the number of the code set n;
c. Building a set of base codes of the code set number n, using symbols zero (‘0’), one (‘1’) and two (‘2’), which:
i. Includes all possible n-character combinations of symbols ‘0’, ‘1’, ‘2’ in the fully filled (without gaps) base grid;
ii. Sorted by the total number of zeros (‘0’) in the descending order;
iii. Divided into groups with equal number of zeros (‘0’) and additionally sorted in ascending lexicographic order within each group.
d. Building the final set of codes by replacing all ones (symbols ‘1’) with binary pairs ‘10’ and all twos (symbols ‘2’) with binary pairs ‘11’ in the base code set.
e. Numbering the prefix codes, built in step d, using ascending consecutive natural numbers, starting with 1.

3. A method of encoding the source data, using the prefix code sets generated by the method of claim 2, consisting of:
a. Establishing the list of unique serial elements the original data is comprised of;
b. Determining the number of appearances of each serial element in the source data;
c. Sorting the resulting list of serial elements by the number of occurrences of individual elements in the source data in descending order, then numbering the serial elements in the list using consecutive natural numbers, starting with 1;
d. Calculating the cardinal number m of the serial elements set (as a total number of unique elements) the original data comprised of, to determine the number n of the correct prefix code set, identified by the minimum number of codes in the set (Mₘᵢₙ), and the maximum number of codes (Mₘₐₓ), provided (Mₘᵢₙ=3ⁿ⁻¹+1)≦m≦(Mₘₐₓ=3n) with an exception of Mₘᵢₙ=3 for the value n=1;
e. Generating m of the foremost prefix codes according to the method of claim 2, to be used from the code set number n, which is established in step d;
f. Assigning all resulting prefix codes generated in step e to every element of the serial elements list, which was sorted and numbered in step c, while matching the prefix code number with the corresponding number of an element from the sorted list;
g. Replacing all elements of the original (source) data, sequentially, from the beginning through the end, with prefix codes assigned to each serial element in step f above.

4. A method of decoding data, encoded earlier by the method of present invention, comprising of:
a. Obtaining from the encoder the identification number n of the prefix code set used for the encoding;
b. Obtaining from the encoder the sorted list of m unique serial elements the source data comprised of, then numbering the sorted serial elements using consecutive natural numbers, starting with 1;
c. Generating m of the foremost prefix codes of set number n obtained in step a, in accordance with the method of claim 2;
d. Assigning every serial element of the sorted list obtained in step b, to every prefix code, generated in step c, while matching the number of the prefix code with the corresponding number of the serial element;
e. Replacing of all prefix codes of data encoded earlier by the method of present invention sequentially, from the beginning through the end, with serial elements assigned to each prefix code in step d above.

5. Because the prefix code sets generated according to the method of claim 2 are predetermined, the codes could either be generated by the encoder or decoder in the process, or stored in advance in the location accessible by the encoder and decoder, either directly in the device memory, or LAN (Intranet) as well as WAN (Internet).

6. Method of prefix code bit-sequence (code signature) formation and prefix code set creation of claim 2 of the present invention allows the convenience of calculation of a prefix code index in the code set (linear list of prefix codes) for faster decoding. Existing variations of bit sequences in prefix codes (for example, replacing all “0” (zeros) with “1” (ones) and vise versa in all prefix codes of the code set) and prefix code compositions within the code set (e.g. re-sorting codes in each of the group g ∈ G in random order) will not yield better degree of compression, than compression achieved by the encoding described in claim 2.

7. Methods of encoding and decoding of the present invention can be used for the purpose of transmission or storage of various types of digital data and implemented in computer hardware or software, local or wide area networks (Intranet and Internet), as well as in telecommunication systems and devices, or any equipment designed to process and store digital data.

8. The invented binary-ternary coding method may be implemented using not only two-pass (static) encoding-decoding algorithm described above, but also a single-pass (adaptive) algorithm.
